(19) United States
(12) Patent Application Publication
(10) Pub. No.: US 2017/0058396 A1
(43) Pub. Date: Mar. 2, 2017

(54) EVAPORATION APPARATUS

(71) Applicant: BOE TECHNOLOGY GROUP CO., LTD., Beijing (CN)

(72) Inventors: Junmin Sun, Beijing (CN); Wei Cui, Beijing (CN); Xindi Zhang, Beijing (CN); Wenyue Fu, Beijing (CN); Changhai Feng, Beijing (CN)

(21) Appl. No.: 15/151,635

(22) Filed: May 11, 2016

(30) Foreign Application Priority Data
Aug. 25, 2015 (CN) 201510527412.5

(51) Int. Cl. C23C 14/24; C23C 14/50

(52) U.S. Cl. CPC C23C 14/243; C23C 14/505

(57) ABSTRACT

An evaporation apparatus is disclosed. The evaporation apparatus includes: an evaporation chamber; a carrier, disposed in the evaporation chamber and employed to bear a substrate onto which an evaporation material is to be evaporated; a longitudinal rail, fixed below the carrier; a first horizontal rail, connected with the longitudinal rail, the first horizontal rail being movable upwardly and downwardly along the longitudinal rail to come close to or move away from the carrier; and a heating source plate, disposed in the evaporation chamber, the heating source plate being movable onto the first horizontal rail and being movable upwardly and downwardly along with the first horizontal rail.

### TECHNICAL FIELD

At least one embodiment of the present disclosure relates to an evaporation apparatus.

### BACKGROUND

In an evaporation apparatus, an evaporation material in solid state is heated into gaseous state or molecular state, and then the evaporation material in gaseous state or molecular state is deposited to a substrate to form a film.

### SUMMARY

According to embodiments of the present disclosure, an evaporation apparatus is provided. The evaporation apparatus comprises an evaporation chamber; a carrier, disposed in the evaporation chamber and employed to bear a substrate onto which an evaporation material is to be evaporated; a longitudinal rail, fixed below the carrier; a first horizontal rail, connected with the longitudinal rail, the first horizontal rail being movable upwardly and downwardly along the longitudinal rail to come close to or move away from the carrier; and a heating source plate, disposed in the evaporation chamber, the heating source plate being movable onto the first horizontal rail and being movable upwardly and downwardly along with the first horizontal rail.

For example, a plurality of the heating source plates are provided.

For example, the plurality of the heating source plates are disposed on different layers with each layer being provided with one heating source plate.

For example, the heating source plate comprises a plurality of heating sources; and the evaporation apparatus further comprises accommodation components that corresponds to the heating sources one by one, each accommodation component is employed to contain the evaporation material, and each heating sources is employed to heat the evaporation material placed inside its corresponding accommodation component so that the evaporation material evaporates upwardly.

For example, the heating source plate comprises a plate-like main part, and the heating sources of the heating source plate are fixed on the plate-like main part.

For example, each accommodation component is placed above its corresponding heating source.

For example, the evaporation apparatus further comprises a plurality of second horizontal rails that correspond to the heating source plates one by one with the heating source plate of each layer being provided on its corresponding second horizontal rail. During the first longitudinal rail moving upwardly and downwardly along the longitudinal rail, the first longitudinal rail is configured to connect with the second horizontal rail and the heating source plate is movable along its corresponding second horizontal rail and the first horizontal rail that is connected with the second horizontal rail.

For example, the first horizontal rail comprises two parallel first guide rails provided at a same height, the second horizontal rail comprises two parallel second guide rails provided a same height, and a distance between the two first guide rails of the first horizontal rail is the same as a distance between the two parallel second guide rails of the second horizontal rail.

For example, the heating source plate of each layer comprises a plate-like main part; a clamping piece is provided on each of two opposite sides of the plate-like main part of the heating source plate of each layer, and the clamping pieces on the two opposite sides of each plate-like main part respectively clamp with the two first guide rail of the first horizontal rail.

For example, the longitudinal rail comprises two parallel longitudinal guide rails; and the evaporation apparatus further comprises a first connection piece, the first connection piece is fixed on the first guide rail and connected with the longitudinal guide rail, and the first connection piece is movable upwardly and downwardly along the longitudinal guide rail.

For example, the evaporation apparatus further comprises a locking piece. After the heating source plate is moved to the first horizontal rail, the locking piece is employed to lock the heating source plate to avoid movement of the heating source plate with respect to the first horizontal rail.

For example, the heating source plates of adjacent layers are spaced from each other by a distance.

For example, the evaporation apparatus further comprises a power unit and a second connection piece. The drive device is disposed outside the evaporation chamber and is connected with the carrier via the second connection piece, and the second connection piece transfers a drive force from the drive device to the carrier to drive the carrier to rotate.

For example, the evaporation chamber comprises a front door and a side door, the front door is employed to add the evaporation material, and the side door is employed to put the substrate into the chamber or take the substrate out of the chamber; the front door is disposed on a side wall of the chamber that is close to the second horizontal rail and perpendicular to a length direction of the second horizontal rail, and the side door is disposed on a side wall of the chamber that is close to the carrier and parallel to the length direction of the second horizontal rail.

For example, the evaporation apparatus further comprises an isolation door. The isolation door is employed to isolate an evaporation-waiting area that is disposed with the second horizontal rail from an evaporation area that is disposed with the first horizontal rail and the longitudinal rail.

### BRIEF DESCRIPTION OF THE DRAWINGS

In order to clearly illustrate the technical solution of the embodiments of the disclosure, the drawings of the embodiments will be briefly described in the following; it is obvious that the described drawings are only related to some embodiments of the disclosure and, it is not limitative to the scope of the present disclosure.

FIG. 1 is a schematic view illustrating an evaporation apparatus according to one technique;

FIG. 2 is a schematic view illustrating a heating source plate of the evaporation apparatus shown in FIG. 1;

FIG. 3 is a schematic view illustrating an evaporation apparatus according to embodiments of the present disclosure;

FIG. 4 is a schematic view illustrating that a heating source plate is moved to a position below a carrier in the evaporation apparatus illustrated in FIG. 3; and

FIG. 5 is a schematic view illustrating the heating source plate of the evaporation apparatus shown in FIG. 3.

### DETAILED DESCRIPTION

In order to make objects, technical details and advantages of the embodiments of the disclosure apparent, the technical solutions of the embodiments will be described in a clearly and fully understandable way in connection with the drawings related to the embodiments of the disclosure. Apparently, the described embodiments are just a part but not all of the embodiments of the disclosure. Based on the described embodiments herein, those skilled in the art can obtain other embodiment(s), without any inventive work, which should be within the scope of the disclosure.

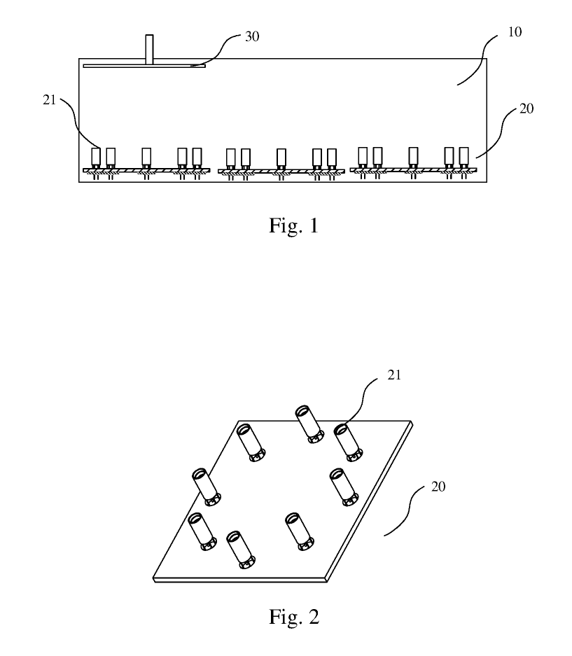

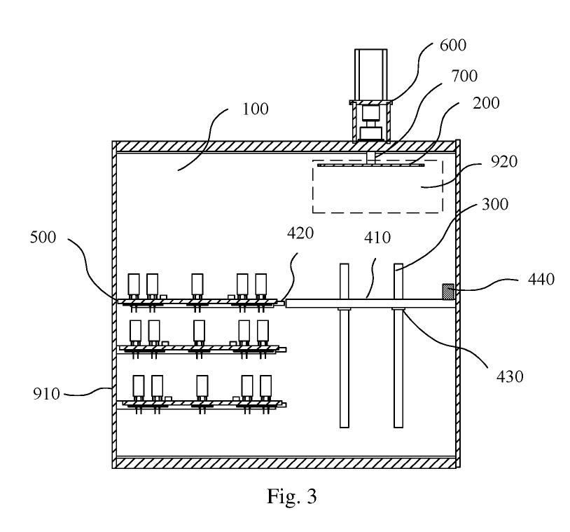

FIG. 1 illustrates an evaporation apparatus. The evaporation apparatus comprises an evaporation chamber 10, a plurality of heating source plates 20 and a horizontally-movable carrier 30, and the carrier is employed to bear a substrate on which an evaporation material is to be deposited. As illustrated in FIG. 2, each heating source plate 20 comprises a plurality of heating sources 21 and each heating source is employed to heat the evaporation material so that the evaporation material evaporates upwardly to deposit on the substrate. A distance between the carrier 30 and the heating source plate 20 disposed below the carrier 30 is fixed. Because the distance between the carrier 30 and the heating source plate 20 is fixed, a distance between the evaporation material serving as an evaporation source and the substrate is fixed. The distance between the evaporation material serving as the evaporation source and the substrate is a key factor to determine the evaporation effect. In the case that the evaporation apparatus is employed to evaporate different evaporation materials, evaporation effects of different evaporation materials can not be controlled for the distance between the evaporation material serving as evaporation source and the substrate is fixed.

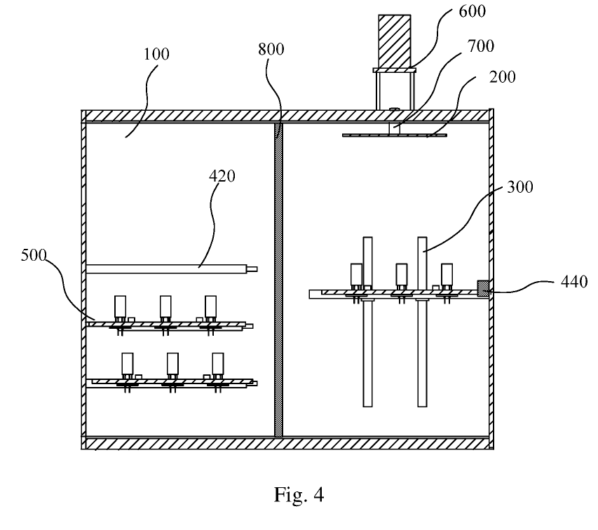

Embodiments of the present disclosure provide an evaporation apparatus. As illustrated in FIG. 3 and FIG. 4, the evaporation apparatus comprises:

an evaporation chamber 100;

a carrier 200, disposed in the evaporation chamber and employed to bear a substrate onto which an evaporation material is to be evaporated;

a longitudinal rail 300, fixed below the carrier;

a first horizontal rail 410, connected with the longitudinal rail, the first horizontal rail 410 being movable upwardly and downwardly along the longitudinal rail 300 to come close to or move away from the carrier 200; and

a heating source plate 500 disposed in the evaporation chamber, and the heating source plate being movable onto the first horizontal rail 410 and being movable upwardly and downwardly along with the first horizontal rail 410.

For example, a plurality of the heating source plates 500 are provided.

In the evaporation apparatus according to the embodiments of the present disclosure, the carrier is provided inside the evaporation chamber, the longitudinal rail is disposed below the carrier, the first horizontal rail connected with the longitudinal rail is movable upwardly and downwardly along the longitudinal rail to come close to or move away from the carrier, that is, the first horizontal rail is movable upwardly and downwardly below the carrier. In this way, the heating source plate after being moved onto the first horizontal rail is movable upwardly and downwardly along with the first horizontal rail below the carrier, that is, a distance between the heating source plate and the carrier is adjustable according to practical requirements. Therefore, a problem that evaporation effect can not be controlled for the distance between the heating source plate and the carrier is fixed and can not be adjusted is solved.

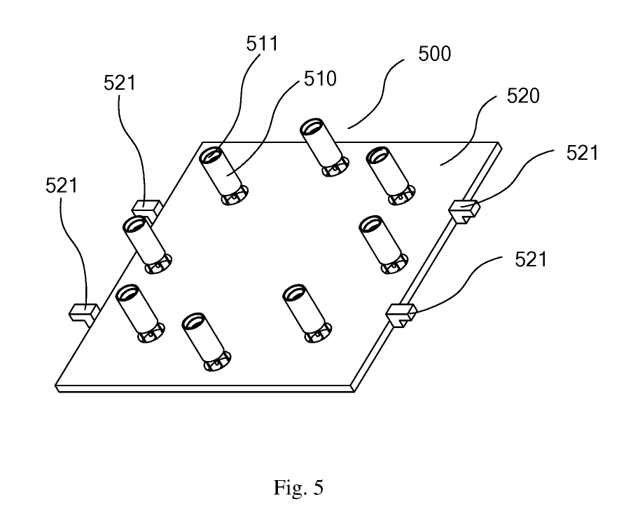

In order that the evaporation material is evaporated and deposited to the substrate carried by the carrier 200, as illustrated in FIG. 5, each heating source plate 500 comprises a plurality of heating sources 510. For example, the evaporation apparatus further comprises accommodation components 511, such as crucibles, that correspond to the heating sources 510 one by one, and each accommodation component is employed to contain the evaporation material. Each heating source is employed to heat the evaporation material placed inside its corresponding accommodation component so that the evaporation material evaporates upwardly. For example, the accommodation component is disposed above the heating source.

For example, the evaporation material is firstly placed inside the accommodation components that correspond to the heating sources of a same heating source plate 500; the heating source plate 500 is pre-heated, and then the heating source plate 500 is moved onto the first horizontal rail 410; and then, the first horizontal rail 410 moves upwardly and downwardly along the longitudinal rail 300 to adjust the distance between the heating source plate 500 and the substrate carried by the carrier 200, that is, the distance between the evaporation material serving as the evaporation source and the substrate is adjustable. During the evaporation material is evaporated to the substrate, evaporation effect is different if the distance between the evaporation material and the substrate is different. In the evaporation apparatus according to the embodiments of the present disclosure, the distance between the evaporation material serving as evaporation source and the substrate onto which the evaporation material is evaporated is adjustable flexibly; in the case that the evaporation apparatus according to the embodiments of the present disclosure is employed to evaporate different kinds of materials, the distance between the evaporation material serving as evaporation source and the substrate is adjustable with respect to each kind of evaporation material so that the evaporation effect of each kind of evaporation material is controlled and optimized.

In order to reduce cross-contamination during pre-heating the plurality of heating source plates, the evaporation apparatus according to the embodiments of the present disclosure is designed as follows. As illustrated in FIG. 3 to FIG. 5, the plurality of heating source plates 500 are disposed on different layers with each layer being disposed with one heating source plate; each heating source plate 500 comprises a plate-like main part 520, and the heating sources 510 of each heating source plate is fixed on the plate-like main part 520.

For example, a same kind of evaporation material is placed inside the accommodation components that correspond to the heating sources of the heating source plate of a same layer. After that, the evaporation material in the accommodation components is heated by the heating sources so that the evaporation material is pre-heated. In the pre-heating process, the evaporation material evaporates upwardly; in this case, the evaporation material inside the accommodation components heated by the heating sources of the heating source plate of a lower layer evaporates upwardly, and the plate-like main part of the heating source plate of an upper layer blocks the evaporation material that evaporates upwardly and the evaporation material that evaporates upwardly deposits onto the plate-like main part of the heating source plate of the upper layer, so that the evaporation material of the lower layer that evaporates upwardly will not drop onto the evaporation material placed in the accommodation components heated by the heating sources of the heating source plate of the upper layer. By providing the plurality of heating source plates 500 on different layers, the cross-contamination of the evaporation materials placed in the accommodation components that correspond to the heating sources of different heating source plates in the pre-heating process is avoided.

For example, as illustrated in FIG. 3 to FIG. 4, the evaporation apparatus further comprises a second horizontal rail 420 that correspond to the heating source plate. For example, a plurality of second horizontal rails 420 are provided to correspond to the heating source plates one by one, and the heating source plate 500 of each layer is provided on its corresponding second horizontal rail 420. During the first longitudinal rail 410 moving upwardly and downwardly along the longitudinal rail 300, the first longitudinal rail 410 is configured to connect with the second horizontal rail and the heating source plate is movable along its corresponding second horizontal rail 420 and the first horizontal rail 410 that is connected with the second horizontal rail.

For example, in the case that the heating source plate is to be used for evaporation, the first horizontal rail 410 moves upwardly or downwardly along the longitudinal rail 300 to a position that is leveled with the second horizontal rail 420 corresponding to the heating source plate, the first horizontal rail is then connected with the second horizontal rail corresponding to the heating source plate, the heating source plate moves along its corresponding second horizontal rail to the first horizontal rail so as to reach a position below the carrier, and then the first horizontal rail is disconnected with the second horizontal rail and the heating source plate moves upwardly and downwardly along with the first horizontal rail below the carrier. After the evaporation process is completed, the heating source plate is returned to its corresponding second horizontal rail. By providing the first horizontal rail and the second horizontal rail, the heating source plate of each layer is easily moved to and moved away from the position below a carrier.

For example, the first horizontal rail 410 comprises two parallel first guide rails provided at a same height. For example, the second horizontal rail 420 comprises two parallel second guide rails provided at a same height. For example, a distance between two first guide rails of the first horizontal rail 410 is the same as a distance between the two second guide rails of the second horizontal rail 420.

For example, as illustrated in FIG. 5, a clamping piece 521 is provided on each of two opposite sides of the plate-like main part 520 of each heating source plate 500. The clamping pieces 521 on the two opposite sides of each plate-like main part are configured to respectively clamp with the second guide rails of the second horizontal rail; and the clamping pieces 521 on two opposite sides of each plate-like main part are configured to respectively clamp with the first guide rails of the first horizontal rail.

In this way, the first horizontal rail comprises the first guide rails, the second horizontal rail comprises the second guide rails, the plate-like main part of the heating source plate is provided with the clamping pieces that are matched with the first guide rails and the second guide rails. By the above simple design, it is realized that the first horizontal rail is connected with the second horizontal rail and the heating source plate is movable along its corresponding second horizontal rail and the first horizontal rail that is connected with the second horizontal rail.

It is to be explained, the first horizontal rail, the second horizontal rail and the clamping pieces that are employed to match the first horizontal rail and the second horizontal rail are a specific implementation mode to connect the first horizontal rail and the second horizontal rail and to allow the heating source plate to move along its corresponding second horizontal rail and the first horizontal rail that is connected with the second horizontal rail, which is provided merely as an example. Other structures may be employed as well, as long as the first horizontal rail is capable of being connected with the second horizontal rail and the heating source plate of each layer is movable along its corresponding second horizontal rail and the first horizontal rail that is connected with the second horizontal rail.

For example, as illustrated in FIG. 3 and FIG. 4, the longitudinal rail 300 comprises two parallel longitudinal guide rails.

For example, the evaporation apparatus further comprises a first connection piece 430 that is matched with the longitudinal rail 300, and the first connection piece 430 is fixed on the first horizontal rail 410 and connected with the longitudinal rail 300. The first connection piece 430 is movable upwardly and downwardly along the longitudinal rail 300 to bring the first horizontal rail 410 to move upwardly and downwardly along the longitudinal rail 300. For example, the first connection piece 430 is fixed on the first horizontal rail 410 and connected with the guide rails of the longitudinal rail 300.

The first connection piece is connected with the longitudinal guide rail and is movable upwardly and downwardly along the longitudinal guide rail. The first connection piece is fixed on the first guide rails of the first horizontal rail 410, so that the first guide rails are movable upwardly and downwardly along the longitudinal rail. The heating source plate moved to the position below the carrier is provided on the first guide rails of the first horizontal rail, and the heating source plate moved to the position below the carrier is movable upwardly and downwardly along with the first horizontal rail so as to come close to or move away from the carrier.

During the evaporation process, it is needed that the distance between the heating source plate moved to the position below the carrier and the substrate onto which the evaporation material is to be evaporated is kept constant; because the position of the substrate is fixed, the heating source plate moved to the position below the carrier should be fixed at an appropriate position. In order that the heating source plate moved to the position below the carrier is fixed at the appropriate position, the evaporation apparatus further comprises a locking piece 440, and the locking piece 440 is employed to lock the heating source plate 500. For example, the locking piece 440 is located on a side of the first horizontal rail 410 away from the second horizontal rail 420. In the case that the heating source plate 500 moves to the first horizontal rail, the locking piece 440 prevents the heating source plate 500 from moving forward to collide with a side wall of the evaporation chamber 100 and the locking piece 400 locks the heating source plate 500 so as to avoid movement of the heating source plate 500 with respect to the first horizontal rail.

For example, in order that maintenance of the evaporation apparatus is convenient and the evaporation material is added easily, as illustrated in FIG. 3, the heating source plates of adjacent layers are spaced from each other by a distance.

During the evaporation process, the substrate onto which the evaporation material deposits sometimes has to be rotated, so as to achieve a better evaporation effect. In this case, for example, the evaporation apparatus further comprises a drive device and a second connection piece. The drive device 600 is disposed outside the evaporation chamber 100 and is connected with the carrier 200 via the second connection piece 700, and the second connection piece 700 transfers a drive force from the drive device 600 to the carrier to drive the carrier to rotate.

For example, as illustrated in FIG. 4, the evaporation apparatus further comprises an isolation door 800, and the isolation door 800 is employed to isolate an evaporation-waiting area that is disposed with the second horizontal rail 420 from an evaporation area that is disposed with the first horizontal rail 410 and the longitudinal rail 300. After the heating source plate 500 is moved to the first horizontal rail 410, the isolation door 800 is closed, so as to ensure evaporation conditions and improve evaporation effect.

For example, the evaporation chamber comprises a front door 910 and a side door 920, the front door 910 is employed to add the evaporation material into the accommodation component, and the side door 920 is employed to put the substrate into the chamber or take the substrate out of the chamber.

The front door 910 is disposed on a side wall of the chamber that is close to the second horizontal rail 420 and perpendicular to a length direction of the second horizontal rail 420, and the side door 920 is disposed on a side wall of the chamber that is close to the carrier 200 and parallel to the length direction of the second horizontal rail 420.

The heating source plate 500 is close to the front door 910, so that the evaporation material is conveniently added into the accommodation component heated by heating source of the heating source plate 500. The carrier 200 is close to the side door 920, so that the substrate is conveniently put onto the carrier or taken from the carrier.

What are described above is related to the illustrative embodiments of the disclosure only and not limitative to the scope of the disclosure. The scopes of the disclosure are defined by the accompanying claims.

This application claims the benefit of Chinese patent application No. 201510527412.5 filled in China on Aug. 25, 2015, which is incorporated by reference herein as a part of this application.

1. An evaporation apparatus, comprising:
an evaporation chamber;
a carrier, disposed in the evaporation chamber and employed to bear a substrate onto which an evaporation material is to be evaporated;
a longitudinal rail, fixed below the carrier;
a first horizontal rail, connected with the longitudinal rail, wherein the first horizontal rail is movable upwardly and downwardly along the longitudinal rail to come close to or move away from the carrier; and
a heating source plate, disposed in the evaporation chamber, wherein the heating source plate is movable onto the first horizontal rail and is movable upwardly and downwardly along with the first horizontal rail.

2. The evaporation apparatus according to claim 1, wherein a plurality of the heating source plates are provided.

3. The evaporation apparatus according to claim 2, wherein the plurality of the heating source plates are disposed on different layers with each layer being provided with one heating source plate.

4. The evaporation apparatus according to claim 1, wherein
the heating source plate comprises a plurality of heating sources; and
the evaporation apparatus further comprises accommodation components that corresponds to the heating sources one by one, each accommodation component is employed to contain the evaporation material, and each heating sources is employed to heat the evaporation material placed inside its corresponding accommodation component so that the evaporation material evaporates upwardly.

5. The evaporation apparatus according to claim 4, wherein the heating source plate comprises a plate-like main part, and the heating sources of the heating source plate are fixed on the plate-like main part.

6. The evaporation apparatus according to claim 4, wherein each accommodation component is placed above its corresponding heating source.

7. The evaporation apparatus according to claim 3, further comprising:
a plurality of second horizontal rails that correspond to the heating source plates one by one with the heating source plate of each layer being provided on its corresponding second horizontal rail,
wherein, during the first longitudinal rail moving upwardly and downwardly along the longitudinal rail, the first longitudinal rail is configured to connect with the second horizontal rail and the heating source plate is movable along its corresponding second horizontal rail and the first horizontal rail that is connected with the second horizontal rail.

8. The evaporation apparatus according to claim 7, wherein the first horizontal rail comprises two parallel first guide rails provided at a same height, the second horizontal rail comprises two parallel second guide rails provided a same height, and a distance between the two first guide rails of the first horizontal rail is the same as a distance between the two parallel second guide rails of the second horizontal rail.

9. The evaporation apparatus according to claim 8, wherein
the heating source plate of each layer comprises a plate-like main part;
a clamping piece is provided on each of two opposite sides of the plate-like main part of the heating source plate of each layer, and the clamping pieces on the two opposite sides of each plate-like main part respectively clamp with the two first guide rail of the first horizontal rail.

10. The evaporation apparatus according to claim 8, wherein
the longitudinal rail comprises two parallel longitudinal guide rails; and
the evaporation apparatus further comprises a first connection piece, the first connection piece is fixed on the first guide rail and connected with the longitudinal guide rail, and the first connection piece is movable upwardly and downwardly along the longitudinal guide rail.

11. The evaporation apparatus according to claim 10, further comprising a locking piece,
wherein, after the heating source plate is moved to the first horizontal rail, the locking piece is employed to lock the heating source plate to avoid movement of the heating source plate with respect to the first horizontal rail.

12. The evaporation apparatus according to claim 3, wherein the heating source plates of adjacent layers are spaced from each other by a distance.

13. The evaporation apparatus according to claim 1, further comprising a power unit and a second connection piece,
wherein the drive device is disposed outside the evaporation chamber and is connected with the carrier via the second connection piece, and the second connection piece transfers a drive force from the drive device to the carrier to drive the carrier to rotate.

14. The evaporation apparatus according to claim 7, wherein
the evaporation chamber comprises a front door and a side door, the front door is employed to add the evaporation material, and the side door is employed to put the substrate into the chamber or take the substrate out of the chamber;
the front door is disposed on a side wall of the chamber that is close to the second horizontal rail and perpendicular to a length direction of the second horizontal rail, and the side door is disposed on a side wall of the chamber that is close to the carrier and parallel to the length direction of the second horizontal rail.

15. The evaporation apparatus according to claim 7, further comprising an isolation door,
wherein the isolation door is employed to isolate an evaporation-waiting area that is disposed with the second horizontal rail from an evaporation area that is disposed with the first horizontal rail and the longitudinal rail.
